(19) United States
(12) Patent Application Publication
(10) Pub. No.: US 2024/0322848 A1
(43) Pub. Date: Sep. 26, 2024

(54) HIGH FREQUENCY CIRCUIT AND COMMUNICATION APPARATUS

(71) Applicant: Murata Manufacturing Co., Ltd., Kyoto (JP)

(72) Inventor: Hideki MUTO, Kyoto (JP)

(21) Appl. No.: 18/732,820

(22) Filed: Jun. 4, 2024

Related U.S. Application Data
(63) Continuation of application No. PCT/JP2022/045590, filed on Dec. 12, 2022.

(30) Foreign Application Priority Data
Dec. 20, 2021 (JP) 2021-205837

(51) Int. Cl. H04B 1/00; H04B 1/18

(52) U.S. Cl. CPC H04B 1/0078; H04B 1/0017; H04B 1/18

(57) ABSTRACT

A high frequency circuit includes: a switch that has terminals, and that switches connection and disconnection between the terminals; a filter that has a first pass band including at least a part of band A and that is connected to one of the terminals; another filter that has a second pass band including at least a part of band B and that is connected to another one of the terminals; and an acoustic wave resonator that has its first end connected to even another of the terminals and its second end connected to the terminal.

### CROSS REFERENCE TO RELATED APPLICATION

This is a continuation of International Application No. PCT/JP2022/045590 filed on Dec. 12, 2022 which claims priority from Japanese Patent Application No. 2021-205837 filed on Dec. 20, 2021. The contents of these applications are incorporated herein by reference in their entireties.

### BACKGROUND ART

### Technical Field

The present disclosure relates to a high frequency circuit and a communication apparatus.

Patent Document 1 discloses a high frequency circuit having a switch IC (Integrated Circuit), a first filter (pass band: first band) connected to a first terminal of two selection terminals of the switch IC, and a second filter (pass band: second band) connected to a second terminal of the two selection terminals. The above high frequency circuit further has a series-connected circuit of a switch element and a capacitor connected between the first terminal and the first filter. Due to the series-connected circuit, the impedance in the second band when viewing the first filter from the first terminal can be positioned on the open side, thereby improving the return loss of the signal in the second band in the path connecting the first terminal and the first filter. Thus, the signals in the first band and second band can be transmitted alone and simultaneously.

Patent Document 1: International Publication No. 2019/172033

### BRIEF SUMMARY

However, recent high frequency circuits are increasingly required to transmit signals in a plurality of bands with close frequencies, so that it is suitable not only to reduce the return loss of signals to be passed through other paths, but also to improve the attenuation characteristics of the filter to enhance isolation with adjacent bands.

The present disclosure provides a high frequency circuit and a communication apparatus capable of transmitting the signals in a plurality of bands with low loss and transmitting the signals in adjacent bands with high attenuation.

In order to achieve the above object, a high frequency circuit according to an aspect of the present disclosure includes: a switch circuit that has a first terminal, a second terminal, a third terminal, and a fourth terminal, and that switches connection and disconnection between the first terminal and the second terminal, switches connection and disconnection between the first terminal and the third terminal, and switches connection and disconnection between the first terminal and the fourth terminal; a first filter that has a first pass band including at least a part of a first band and that is connected to the second terminal; a second filter that has a second pass band including at least a part of a second band and that is connected to the third terminal; and an acoustic wave resonator that has its first end connected to the fourth terminal and its second end connected to the second terminal.

According to the present disclosure, it is possible to provide a high frequency circuit and a communication apparatus capable of transmitting the signals in a plurality of bands with low loss and transmitting the signals in adjacent bands with high attenuation.

### BRIEF DESCRIPTION OF THE DRAWINGS

FIG. 1 is a circuit configuration diagram of a high frequency circuit and a communication apparatus according to an embodiment.

FIG. 2A is a plan view and cross-sectional view schematically illustrating a first structural example of an acoustic wave resonator according to the embodiment.

FIG. 2B is a cross-sectional view schematically illustrating a second structural example of the acoustic wave resonator according to the embodiment.

FIG. 2C is a cross-sectional view schematically illustrating a third structural example of the acoustic wave resonator according to the embodiment.

FIG. 3 is a graph showing filter bandpass characteristics of the high frequency circuit according to the embodiment.

FIG. 4A is a circuit state diagram of the high frequency circuit according to the embodiment, when the signals of bands A and B are transmitted simultaneously (case 1).

FIG. 4B is a circuit state diagram of the high frequency circuit according to the embodiment, when the signal of band A is transmitted alone (case 1).

FIG. 5A is a circuit state diagram of the high frequency circuit according to the embodiment, when the signals of bands A and B are transmitted simultaneously (case 2).

FIG. 5B is a circuit state diagram of the high frequency circuit according to the embodiment, when the signal of band A is transmitted alone (case 2).

FIG. 6 is a circuit configuration diagram of a high frequency circuit according to Variation 1.

FIG. 7 is a circuit configuration diagram of a high frequency circuit according to Variation 2.

FIG. 8 is a circuit configuration diagram of a high frequency circuit according to Variation 3.

FIG. 9 is a circuit configuration diagram of a high frequency circuit according to Variation 4.

FIG. 10 is a graph showing filter bandpass characteristics of the high frequency circuit according to Variation 4.

FIG. 11A is a circuit state diagram of the high frequency circuit according to Variation 4, when the signal of band A is transmitted alone.

FIG. 11B is a circuit state diagram of the high frequency circuit according to Variation 4, when the signal of band C is transmitted alone.

FIG. 11C is a circuit state diagram of the high frequency circuit according to Variation 4, when the signal of band A and the signal of band B are transmitted simultaneously.

### DETAILED DESCRIPTION

Embodiments of the present disclosure will be described in detail below with reference to the drawings. It should be noted that all the embodiments described below are comprehensive or specific examples. The numerical values, shapes, materials, components, arrangement and connection forms of components, and the like shown in the following embodiments are examples and are not intended to limit the present disclosure.

It should be noted that each drawing is schematic with emphasis, omissions, or proportions adjusted as appropriate to illustrate the present disclosure, and is not necessarily strictly illustrative, and may differ from actual shapes, positional relationships, and proportions. In each drawing, substantially identical components are denoted by the same reference signs, and duplicate descriptions may be omitted or simplified.

In the present disclosure, the term “connected” means not only when directly connected by connection terminals and/or wiring conductors, but also when electrically connected via other circuit elements. The expression “connected between A and B” means connected to A and B on a path that connects A and B.

In the present disclosure, the term “path” means a transmission line composed of a wiring through which a high frequency signal propagates, electrodes directly connected to the wiring, terminals directly connected to the wiring or the electrodes, and/or the like.

In the component arrangement of the present disclosure, terms indicating relationships between elements, such as “parallel” and “orthogonal”, and terms indicating the shape of elements, such as “rectangular”, as well as numerical ranges, do not represent only strict meanings, but also include substantially equivalent ranges, for example, errors of about several percent.

In the present disclosure, the expression “the component A is arranged in series in the path B” means that both the signal input end and the signal output end of the component A are connected to the wiring, the electrodes or the terminals constituting the path B.

### Embodiments

### [1 Circuit Configuration of High Frequency Circuit 1 and Communication Apparatus 5]

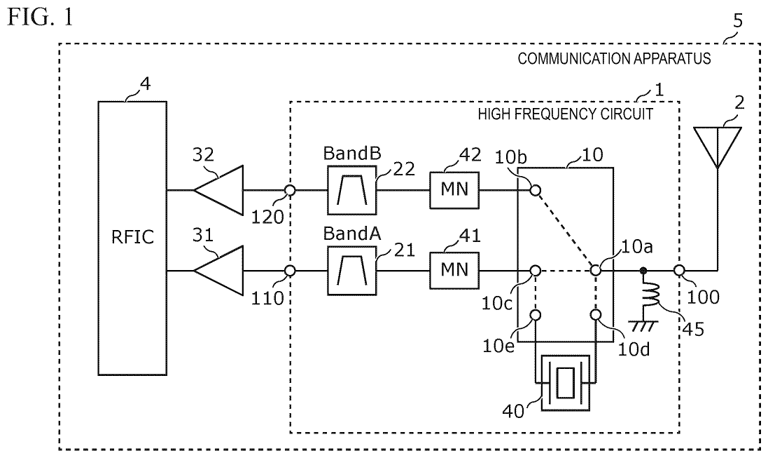

The circuit configuration of a high frequency circuit 1 and a communication apparatus 5 according to an embodiment are described with reference to FIG. 1. FIG. 1 is a circuit configuration diagram of the high frequency circuit 1 and the communication apparatus 5 according to the embodiment.

### [1.1 Circuit Configuration of Communication Apparatus 5]

First, the circuit configuration of the communication apparatus 5 is described. As shown in FIG. 1, the communication apparatus 5 according to the present embodiment includes the high frequency circuit 1, an antenna 2, low-noise amplifiers 31 and 32, and a radio frequency integrated circuit (RFIC) 4.

The high frequency circuit 1 transmits a high frequency signal between the antenna 2 and the RFIC 4. The detailed circuit configuration of the high frequency circuit 1 is described below.

The antenna 2 is connected to an antenna connection terminal 100 of the high frequency circuit 1, transmits the high frequency signal output from the high frequency circuit 1, and receives a high frequency signal from outside and outputs the received high frequency signal to the high frequency circuit 1.

The low-noise amplifier 31 has its input end connected to a high frequency output terminal 110 of the high frequency circuit 1 and its output end connected to the RFIC 4 to amplify a received signal of band A. The low-noise amplifier 32 has its input end connected to a high frequency output terminal 120 of the high frequency circuit 1 and its output end connected to the RFIC 4 to amplify a received signal of band B.

The RFIC 4 is an example of a signal processing circuit that processes high frequency signals. Specifically, the RFIC 4 performs signal processing on the received signal input via a reception path of the high frequency circuit 1 by down-conversion or the like, and outputs a received signal generated by performing the signal processing to a baseband integrated circuit (BBIC, not shown). Further, the RFIC 4 performs signal processing on a transmission signal input from the BBIC by up-conversion or the like, and outputs a transmission signal generated by performing the signal processing to a transmission path of the high frequency circuit 1. Further, the RFIC 4 functions as a control unit to control the connection of a switch 10 based on the band (frequency band) used. Further, the RFIC 4 has a control unit that controls the low-noise amplifiers 31 and 32 and the like. Note that some or all of the functions of the RFIC 4 as a control unit may be implemented outside of the RFIC 4, for example, in the BBIC or the high frequency circuit 1.

In the communication apparatus 5 according to the present embodiment, the antenna 2 is an optional component. The low-noise amplifiers 31 and 32 may also be included in the high frequency circuit 1.

### [1.2 Circuit Configuration of High Frequency Circuit 1]

Next, the circuit configuration of the high frequency circuit 1 is described. As shown in FIG. 1, the high frequency circuit 1 includes the switch 10, filters 21 and 22, an acoustic wave resonator 40, matching circuits 41 and 42, an inductor 45, the antenna connection terminal 100, and the high frequency output terminals 110 and 120.

The antenna connection terminal 100 is connected to the antenna 2.

The switch 10 is an example of a switch circuit and has a terminal 10a (first terminal), a terminal 10b (third terminal), a terminal 10c (second terminal), a terminal 10d (fourth terminal), and a terminal 10e (fifth terminal). The switch 10 switches the connection and disconnection between the terminal 10a and the terminal 10c, switches the connection and disconnection between the terminal 10a and the terminal 10b, switches the connection and disconnection between the terminal 10a and the terminal 10d, and switches the connection and disconnection between the terminal 10c and the terminal 10e.

The switch 10 is a multi-connection type switch circuit composed of, for example, an SPST (single pole single throw) type first switch element having the terminal 10a and the terminal 10b, an SPST type second switch element having the terminal 10a and the terminal 10c, an SPST type third switch element having the terminal 10a and the terminal 10d and an SPST type fourth switch element having the terminal 10c and the terminal 10e. Thus, the switch 10 can simultaneously perform two or more of the following connections: the connection between the terminal 10a and the terminal 10c, the connection between the terminal 10a and the terminal 10b, the connection between the terminal 10a and the terminal 10d, and the connection between the terminal 10c and the terminal 10e. The switch 10 simultaneously switches the connection and disconnection between the terminal 10a and the terminal 10d, and the connection and disconnection between the terminal 10c and the terminal 10e. In other words, when the terminal 10a and the terminal 10d are connected, the terminal 10c and the terminal 10e are connected; and when the terminal 10a and the terminal 10d are disconnected, the terminal 10c and the terminal 10e are disconnected.

The filter 21 is an example of a first filter, with its input end connected to the terminal 10c via the matching circuit 41 and its output end connected to the high frequency output terminal 110, and has a first pass band that includes at least a part of band A (first band).

The filter 22 is an example of a second filter, with its input end connected to the terminal 10b via the matching circuit 42 and its output end connected to the high frequency output terminal 120, and has a second pass band that includes at least a part of band B (second band).

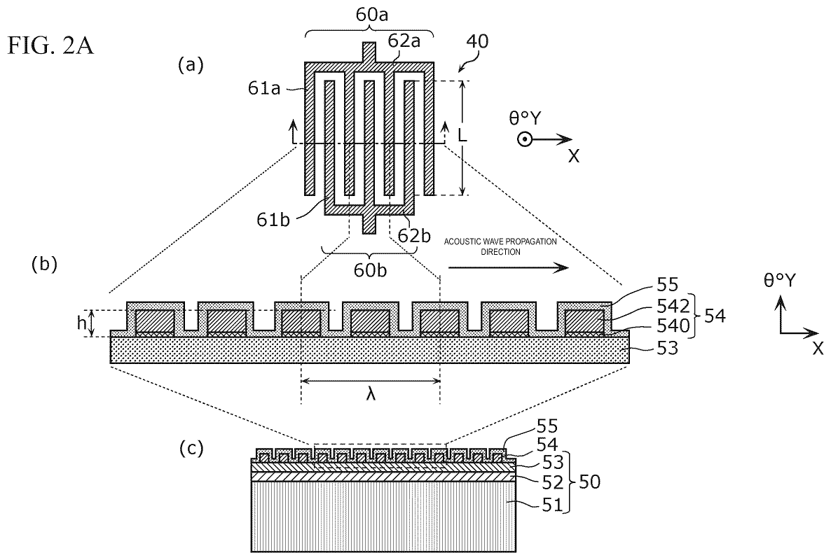

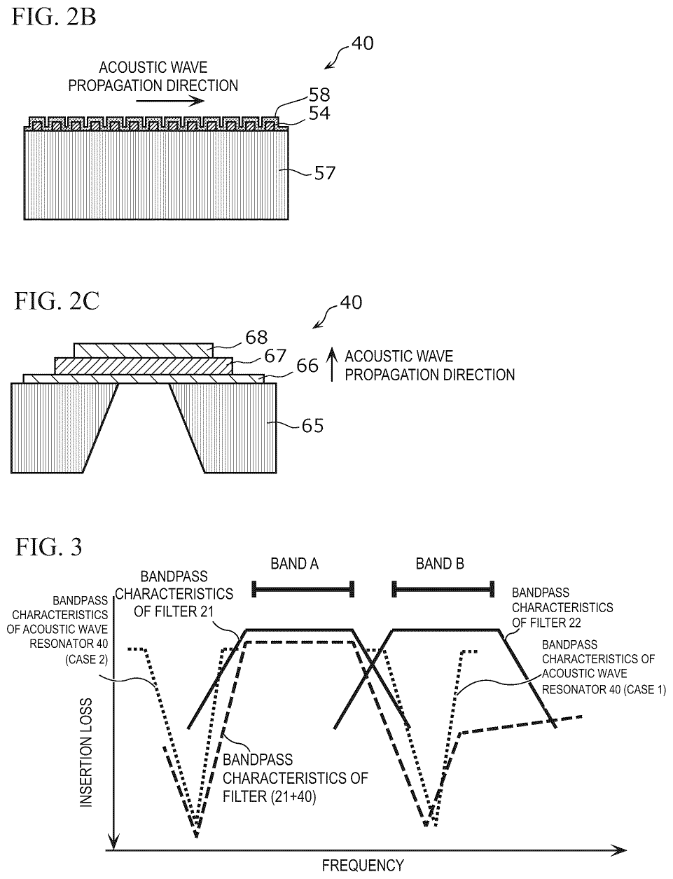

The acoustic wave resonator 40 has its first end connected to the terminal 10d and its second end connected to the terminal 10e. The structure of the acoustic wave resonator 40 will be described later with reference to FIGS. 2A to 2C.

The inductor 45 is connected between a path connecting the antenna connection terminal 100 and the terminal 10a and the ground. The inductor 45 is a matching element for performing impedance matching between the antenna 2 and the switch 10. Note that the inductor 45 may also be arranged in series in a path connecting the antenna connection terminal 100 and the terminal 10a.

The matching circuit 41 is connected between the terminal 10c and the filter 21 to perform impedance matching between the switch 10 and the filter 21. The matching circuit 42 is connected between the terminal 10b and the filter 22 to perform impedance matching between the switch 10 and the filter 22. The matching circuits 41 and 42 include, for example, at least one of an inductor and a capacitor.

In the high frequency circuit 1 according to the present embodiment, the terminal 10e may be omitted. In such a case, the second end of the acoustic wave resonator 40 is directly connected to the terminal 10c.

The high frequency circuit 1 does not have to include the inductor 45 and the matching circuits 41 and 42.

With the above configuration of high frequency circuit 1, it is possible to realize transmission of band A alone, transmission of band B alone, and transmission of band A and band B simultaneously. When transmitting the signal of band A alone and when transmitting the signals of band A and band B simultaneously, it is possible to select, by the switch 10, whether or not to connect the acoustic wave resonator 40 in series with the filter 21. The acoustic wave resonator 40 has a capacitive impedance and further, can form an attenuation pole in the vicinity of the anti-resonant frequency. Thus, not only the return loss of the signal of band B is reduced by the capacitive impedance of the acoustic wave resonator 40, but also the attenuation characteristics of the filter 21 can be improved. Thus, it is possible to provide the high frequency circuit 1 that can transmit the signals in a plurality of bands with low loss and transmit the signals in adjacent bands with high attenuation.

Band A and band B are frequency bands predefined by standardization organizations (for example, 3GPP (registered trademark), IEEE (Institute of Electrical and Electronics Engineers) and the like) for communication systems built using RAT (Radio Access Technology). In the present embodiment, communication systems such as, but not limited to, 4G (4th Generation)-LTE (Long Term Evolution) systems, 5G (5th Generation)-NR (New Radio) systems, and WLAN (Wireless Local Area Network systems, can be used.

### [1.3 Structure of Acoustic Wave Resonator 40]

Next, the structure of the acoustic wave resonator 40 is described.

FIG. 2A is a plan view and cross-sectional view schematically illustrating a first structural example of the acoustic wave resonator 40 according to the embodiment. The acoustic wave resonator 40 shown in FIG. 2A is intended to explain a typical structure of an acoustic wave resonator, and the number and the length of electrode fingers constituting the electrodes is not limited to those shown in the drawing.

The acoustic wave resonator 40 is composed of a substrate 50 having piezoelectricity and comb-shaped electrodes 60a and 60b.

As shown in (a) of FIG. 2A, a pair of comb-shaped electrodes 60a and 60b facing each other are formed on the substrate 50. The comb-shaped electrode 60a is composed of a plurality of electrode fingers 61a parallel to each other and a busbar electrode 62a connecting the plurality of electrode fingers 61a. The comb-shaped electrode 60b is composed of a plurality of electrode fingers 61b parallel to each other and a busbar electrode 62b connecting the plurality of electrode fingers 61b. The plurality of electrode fingers 61a and 61b are formed along a direction orthogonal to the acoustic wave propagation direction (X-axis direction).

An IDT electrode 54, which is composed of the plurality of electrode fingers 61a and 61b and the busbar electrodes 62a and 62b, has a multilayer structure with an adhesion layer 540 and a main electrode layer 542, as shown in (b) of FIG. 2A.

The adhesion layer 540 is a layer to improve the adhesion between the substrate 50 and the main electrode layer 542, and Ti, for example, is used as the material of the adhesion layer 540. Al containing 1% Cu, for example, is used as the material of the main electrode layer 542. A protective layer 55 is formed to cover the comb-shaped electrodes 60a and 60b. The protective layer 55 is a layer for protecting the main electrode layer 542 from the external environment, adjusting frequency-temperature characteristics, and enhancing moisture resistance, and the like; and is, for example, a dielectric film mainly composed of silicon dioxide.

The materials constituting the adhesion layer 540, the main electrode layer 542, and the protective layer 55 are not limited to those described above. Further, the IDT electrode 54 does not have to have the above multilayer structure. The IDT electrode 54 may be composed of a metal, such as Ti, Al, Cu, Pt, Au, Ag, Pd or the like or an alloy thereof, and may also be composed of a plurality of multilayer bodies composed of the above metals or alloys. The protective layer 55 does not have to be formed.

Next, the multilayer structure of the substrate 50 is described.

As shown in (c) of FIG. 2A, the substrate 50 includes a high acoustic velocity support substrate 51, a low acoustic velocity film 52, and a piezoelectric film 53, and has a structure obtained by stacking the high acoustic velocity support substrate 51, the low acoustic velocity film 52, and the piezoelectric film 53 in this order.

The piezoelectric film 53 is composed of, for example, a θ° Y-cut X propagating LiTaO₃ piezoelectric single crystal or piezoelectric ceramic (a lithium tantalate single crystal or ceramic cut by a plane having a normal line which is an axis obtained by rotating θ° From the Y-axis with the X-axis as a center axis, in which surface acoustic waves propagate in the X-axis direction). Note that the material and cut-angle θ of the piezoelectric single crystal used as the piezoelectric film 53 are appropriately selected according to the required specifications of each filter.

The high acoustic velocity support substrate 51 is a substrate that supports the low acoustic velocity film 52, the piezoelectric film 53, and the IDT electrode 54. Further, the high acoustic velocity support substrate 51 is a substrate in which the acoustic velocity of the bulk wave in the high acoustic velocity support substrate 51 is faster than an acoustic wave, such as a surface acoustic wave or a boundary wave, propagating through the piezoelectric film 53, and functions to confine the surface acoustic wave in an area where the piezoelectric film 53 and the low acoustic velocity film 52 are stacked so that the surface acoustic wave does not leak downward from under the high acoustic velocity support substrate 51. The high acoustic velocity support substrate 51 is, for example, a silicon substrate.

The low acoustic velocity film 52 is a film in which the acoustic velocity of the bulk wave in the low acoustic velocity film 52 is lower than that of the bulk wave propagating through the piezoelectric film 53, and is arranged between the piezoelectric film 53 and the high acoustic velocity support substrate 51. Due to such a structure and the fact that the energy is concentrated in a medium in which the acoustic wave is inherently low acoustic velocity, the leakage of the surface acoustic wave energy out of the IDT electrode is suppressed. The low acoustic velocity film 52 is, for example, a film mainly composed of silicon dioxide.

With the above-described multilayer structure of the substrate 50, it is possible to greatly increase the Q value at the resonant frequency and anti-resonant frequency compared to the conventional structure where a single layer is used as the piezoelectric substrate. In other words, since an acoustic wave resonator with high Q value can be configured, it is possible to configure a filter with low insertion loss using such an acoustic wave resonator.

The acoustic wave resonator 40 shown in FIG. 2A exhibits a capacitive impedance, except for the frequency range between the resonant frequency and the anti-resonant frequency, for propagating a high frequency signal between the pair of comb-shaped electrodes 60a and 60b facing each other.

The high acoustic velocity support substrate 51 may have a structure obtained by stacking a support substrate and a high acoustic velocity film, which is a film in which the acoustic velocity of the propagating bulk wave is higher than that of the acoustic wave, such as a surface acoustic wave or a boundary wave, propagating through the piezoelectric film 53. In such a case, examples of materials possible to be used as the support substrate include: a piezoelectric body such as sapphire, lithium tantalate, lithium niobate, and quartz; various ceramics, such as alumina, magnesia, silicon nitride, aluminum nitride, silicon carbide, zirconia, cordierite, mullite, steatite, and forsterite; a dielectric such as glass; a semiconductor such as silicon and gallium nitride; and a resin substrate. Further, various high acoustic velocity materials can be used for the high acoustic velocity film, and examples of the high acoustic velocity materials include: aluminum nitride, aluminum oxide, silicon carbide, silicon nitride, silicon oxynitride, a DLC film, diamond; a medium mainly composed of these materials; and a medium mainly composed of a mixture of these materials.

FIG. 2B is a cross-sectional view schematically illustrating a second structural example of the acoustic wave resonator 40 according to the embodiment. In the acoustic wave resonator 40 shown in FIG. 2A, the IDT electrode 54 is formed on the substrate 50 having the piezoelectric film 53; however, the substrate on which the IDT electrode 54 is formed may be a piezoelectric single crystal substrate 57 composed of a single layer of a piezoelectric layer, as shown in FIG. 2B. The piezoelectric single crystal substrate 57 is composed of, for example, a piezoelectric single crystal of LiNbO₃. The acoustic wave resonator according to the present example is composed of a LiNbO₃ piezoelectric single crystal substrate 57, the IDT electrode 54, and a protective layer 58 formed on the piezoelectric single crystal substrate 57 and the IDT electrode 54.

The piezoelectric film 53 and the piezoelectric single crystal substrate 57 described above may be modified as appropriate in multilayer structure, material, cut-angle, and thickness, in accordance with the required bandpass characteristics of the acoustic wave filter device. Even an acoustic wave resonator using a LiTaO₃ piezoelectric substrate or the like with a cut-angle other than the cut-angle described above can have the same effect as the acoustic wave resonator 40 using the piezoelectric film 53 described above.

The substrate on which the IDT electrode 54 is formed may have a structure obtained by stacking a support substrate, an energy confinement layer, and a piezoelectric film in this order. The IDT electrode 54 is formed on the piezoelectric film. The piezoelectric film is, for example, made of a LiTaO₃ piezoelectric single crystal or piezoelectric ceramic. The support substrate is a substrate that supports the piezoelectric film, the energy confinement layer, and the IDT electrode 54.

The energy confinement layer is composed of one or more layers, and the velocity of the bulk acoustic wave propagating through at least one of the layers is greater than the velocity of the acoustic wave propagating in the vicinity of the piezoelectric film. For example, the energy confinement layer may have a multilayer structure of a low acoustic velocity layer and a high acoustic velocity layer. The low acoustic velocity layer is a film in which the acoustic velocity of the bulk wave in the low acoustic velocity layer is lower than the acoustic velocity of the acoustic wave propagating through the piezoelectric film. The high acoustic velocity layer is a film in which the acoustic velocity of the bulk wave in the high acoustic velocity layer is faster than the acoustic velocity of the acoustic wave propagating through the piezoelectric film. The support substrate may be used as the high acoustic velocity layer.

The energy confinement layer may be an acoustic impedance layer having a structure obtained by alternately stacking a low acoustic impedance layer with relatively low acoustic impedance and a high acoustic impedance layer with relatively high acoustic impedance.

The acoustic wave resonator 40 shown in FIG. 2B exhibits a capacitive impedance, except for the frequency range between the resonant frequency and the anti-resonant frequency, for propagating a high frequency signal between the pair of comb-shaped electrodes 60a and 60b facing each other.

Here, an example (embodiment) of electrode parameters of the IDT electrode constituting the acoustic wave resonator 40 will be described.

The wavelength of the acoustic wave resonator is defined by the wavelength λ, which is the repetition period of the plurality of electrode fingers 61a or 61b constituting the IDT electrode 54 shown in (b) of FIG. 2A. The electrode finger pitch is ½ of the wavelength λ and is defined as (W+S), where W is the line width of the electrode fingers 61a and 61b that constitute the comb-shaped electrodes 60a and 60b, respectively, and S is the space width between adjacent electrode finger 61a and electrode finger 61b. Further, as shown in (a) of FIG. 2A, the intersecting width L of the pair of comb-shaped electrodes 60a and 60b is the length of the overlapping electrode fingers when viewed from the acoustic wave propagation direction (X-axis direction) between the electrode finger 61a and the electrode finger 61b. The electrode duty of each acoustic wave resonator is the occupancy rate of the line width of the plurality of electrode fingers 61a and 61b, and is defined as W/(W+S), which represents the ratio of the line width to the sum of the line width and the space width of the plurality of electrode fingers 61a and 61b. The height of the comb-shaped electrodes 60a and 60b is h. In the following description, parameters related to the shape of the IDT electrode of the acoustic wave resonator, such as the wavelength λ, the electrode finger pitch, the intersecting width L, the electrode duty, and the height h of the IDT electrode 54, are defined as the electrode parameters.

If the space between adjacent electrode fingers is not constant in the IDT electrode 54, the electrode finger pitch of the IDT electrode 54 is defined by the average electrode finger pitch of the IDT electrode 54. The average electrode finger pitch of the IDT electrode 54 is defined as Di/(Ni−1), where Ni is the total number of the electrode fingers 61a and 61b in the IDT electrode 54, and Di is the distance between the centers of the electrode finger of the IDT electrode 54 located at one end in the acoustic wave propagation direction and the electrode finger of the IDT electrode 54 located at the other end in the acoustic wave propagation direction.

For example, if the film thickness of the IDT electrode, the film thickness of the protective layer, and the electrode duty are constant, the larger the electrode finger pitch of the IDT electrode, the more the resonant frequency and anti-resonant frequency of the surface acoustic wave resonator shift to the lower frequency side.

FIG. 2C is a cross-sectional view schematically illustrating a third structural example of the acoustic wave resonator 40 according to the embodiment. FIG. 2C shows a bulk acoustic wave resonator as the acoustic wave resonator 40. As shown in FIG. 2C, the bulk acoustic wave resonator has, for example, a support substrate 65, a lower electrode 66, a piezoelectric layer 67, and an upper electrode 68, and is formed by stacking the support substrate 65, the lower electrode 66, the piezoelectric layer 67, and the upper electrode 68 in this order.

The support substrate 65 is a substrate for supporting the lower electrode 66, the piezoelectric layer 67, and the upper electrode 68, and is, for example, a silicon substrate. The support substrate 65 has a cavity provided in the area where it contacts the lower electrode 66. Thus, the piezoelectric layer 67 can be freely vibrated.

The lower electrode 66 is an example of a first electrode and is formed on one side of the support substrate 65. The upper electrode 68 is an example of a second electrode and is formed on one side of the support substrate 65. Al containing 1% Cu, for example, is used as the material of the lower electrode 66 and the upper electrode 68.

The piezoelectric layer 67 is formed between the lower electrode 66 and the upper electrode 68. The piezoelectric layer 67, for example, is mainly composed of at least one of ZnO (zinc oxide), AlN (aluminum nitride), PZT (lead zirconate titanate), KN (potassium niobate), LN (lithium niobate), LT (lithium tantalate), crystal, and LiBO (lithium borate).

The bulk acoustic wave resonator with the above-described multilayer structure generates resonance by applying electrical energy between the lower electrode 66 and the upper electrode 68 to induce a bulk acoustic wave in the piezoelectric layer 67. The bulk acoustic wave generated by the bulk acoustic wave resonator propagates between the lower electrode 66 and the upper electrode 68 in a direction perpendicular to the film surface of the piezoelectric layer 67. In other words, the bulk acoustic wave resonator is a resonator that uses a bulk acoustic wave.

For example, the larger the thickness of the piezoelectric layer 67, the more the resonant frequency and anti-resonant frequency of the bulk acoustic wave resonator shift to the lower frequency side.

Further, the acoustic wave resonator 40 shown in FIG. 2C exhibits a capacitive impedance, except for the frequency range between the resonant frequency and the anti-resonant frequency, for propagating a high frequency signal between the lower electrode 66 and the upper electrode 68 facing each other.

### [1.4 Signal Transmission State of High Frequency Circuit 1]

Next, the signal transmission state of band A and band B in the high frequency circuit 1 is described.

FIG. 3 is a graph showing filter bandpass characteristics of the high frequency circuit 1 according to the embodiment. FIG. 3 illustrates the bandpass characteristics of the filters 21 and 22, the acoustic wave resonator 40, and a series-connected circuit of the filter 21 and the acoustic wave resonator 40. As shown in FIG. 3, a first example (case 1) is a case where high attenuation in the frequency band of band B is required during signal transmission of band A. A second example (case 2) is a case where high attenuation in the frequency band lower than band A is required during signal transmission of band A.

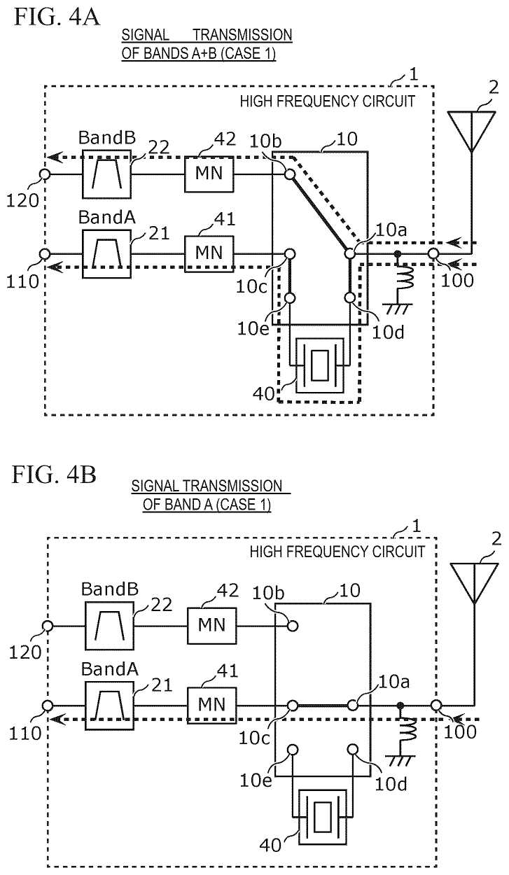

FIG. 4A is a circuit state diagram of the high frequency circuit 1 according to the embodiment, when the signals of bands A and B are transmitted simultaneously (case 1). FIG. 4B is a circuit state diagram of the high frequency circuit 1 according to the embodiment, when the signal of band A is transmitted alone (case 1).

When the signal of band A and the signal of band B are transmitted simultaneously in the first example described above, since the signal of band B interferes with the signal of band A, it is assumed that the requirement for high attenuation in the frequency band of band B cannot be satisfied. In such a case, as shown in FIG. 4A, the acoustic wave resonator 40 is connected in series with the filter 21 to ensure high attenuation in the frequency band of band B in the signal transmission path of band A. In the present example, the anti-resonant frequency of the acoustic wave resonator 40 can be included in the pass band of the filter 22. Thus, the series-connected circuit of the filter 21 and the acoustic wave resonator 40 can have bandpass characteristics with high attenuation in band B.

Specifically, as shown in FIG. 4A, in the switch 10, the terminal 10a and the terminal 10b are connected, the terminal 10a and the terminal 10d are connected, the terminal 10c and the terminal 10e are connected, and the terminal 10a and the terminal 10c are disconnected. Thus, the signal of band A passes through the antenna 2, the antenna connection terminal 100, the terminal 10a, the terminal 10d, the acoustic wave resonator 40, the terminal 10e, the terminal 10c, the matching circuit 41, and the filter 21 to be output from the high frequency output terminal 110. The signal of band B passes through the antenna 2, the antenna connection terminal 100, the terminal 10a, the terminal 10b, the matching circuit 42, and the filter 22 to be output from the high frequency output terminal 120.

Thus, when the signals of bands A and B are transmitted simultaneously, it is possible not only to reduce the return loss of the signal of band B in the signal path of band A from the terminal 10a to the high frequency output terminal 110, but also to improve the attenuation in the frequency band of band B in the signal path of band A. Thus, it is possible to transmit the signals of band A and band B with low loss, and transmit the signal of band B, in the signal transmission of band A, with high attenuation.

When the signal of band A, among band A and band B, is transmitted alone in the first example described above, since the signal of band B does not interfere with the signal of band A, it is assumed that high attenuation in the frequency band of band B can be ensured by the filter 21 only. In such a case, as shown in FIG. 4B, the signal in band A is transmitted without necessarily connecting the acoustic wave resonator 40 to the filter 21.

Specifically, as shown in FIG. 4B, in the switch 10, the terminal 10a and the terminal 10b are disconnected, the terminal 10a and the terminal 10d are disconnected, the terminal 10c and the terminal 10e are disconnected, and the terminal 10a and the terminal 10c are connected. Thus, the signal of band A passes through the antenna 2, the antenna connection terminal 100, the terminal 10a, the terminal 10c, the matching circuit 41, and the filter 21 to be output from the high frequency output terminal 110.

Thus, when the signal of band A is transmitted alone, the signal of band A can be transmitted without necessarily interference from the signal of band B; and further, since the acoustic wave resonator 40 is not connected, the signal of band A can be transmitted with low loss.

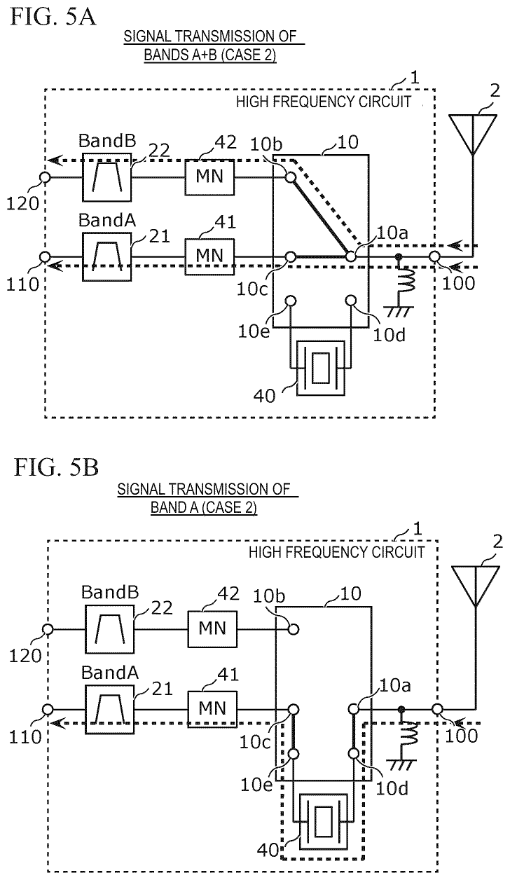

FIG. 5A is a circuit state diagram of the high frequency circuit 1 according to the embodiment, when the signals of bands A and B are transmitted simultaneously (case 2). FIG. 5B is a circuit state diagram of the high frequency circuit 1 according to the embodiment, when the signal of band A is transmitted alone (case 2).

When the signal of band A and the signal of band B are transmitted simultaneously in the second example described above, it is assumed that high attenuation in the frequency band of band B is not required. In such a case, as shown in FIG. 5A, the acoustic wave resonator 40 is not connected to the filter 21, and low-loss signal transmission of band A is ensured.

Specifically, as shown in FIG. 5A, in the switch 10, the terminal 10a and the terminal 10b are connected, the terminal 10a and the terminal 10d are disconnected, the terminal 10c and the terminal 10e are disconnected, and the terminal 10a and the terminal 10c are connected. Thus, the signal of band A passes through the antenna 2, the antenna connection terminal 100, the terminal 10a, the terminal 10c, the matching circuit 41, and the filter 21 to be output from the high frequency output terminal 110. The signal of band B passes through the antenna 2, the antenna connection terminal 100, the terminal 10a, the terminal 10b, the matching circuit 42, and the filter 22 to be output from the high frequency output terminal 120.

Thus, when the signals of bands A and B are transmitted simultaneously, since the acoustic wave resonator 40 is not connected, the signals of band A and band B can be transmitted with low loss.

In the second example described above, when the signal of band A, among band A and band B, is transmitted alone, it is assumed that, for example, high attenuation in the frequency band lower than band A is required. In such a case, as shown in FIG. 5B, by connecting the acoustic wave resonator 40 to the filter 21, high attenuation in the frequency band lower than band A is ensured.

Specifically, as shown in FIG. 5B, in the switch 10, the terminal 10a and the terminal 10b are disconnected, the terminal 10a and the terminal 10d are connected, the terminal 10c and the terminal 10e are connected, and the terminal 10a and the terminal 10c are disconnected. Thus, the signal of band A passes through the antenna 2, the antenna connection terminal 100, the terminal 10a, the terminal 10d, the acoustic wave resonator 40, the terminal 10e, the terminal 10c, the matching circuit 41, and the filter 21 to be output from the high frequency output terminal 110. In the present example, the anti-resonant frequency of the acoustic wave resonator 40 can be included in the frequency band lower than band A. Thus, the series-connected circuit of the filter 21 and the acoustic wave resonator 40 can have bandpass characteristics with high attenuation in the frequency band lower than band A.

Thus, when the signal of band A is transmitted alone, attenuation in a predetermined frequency band can be enhanced.

### [1.5 Circuit Configuration of High Frequency Circuit 1A According to Variation 1]

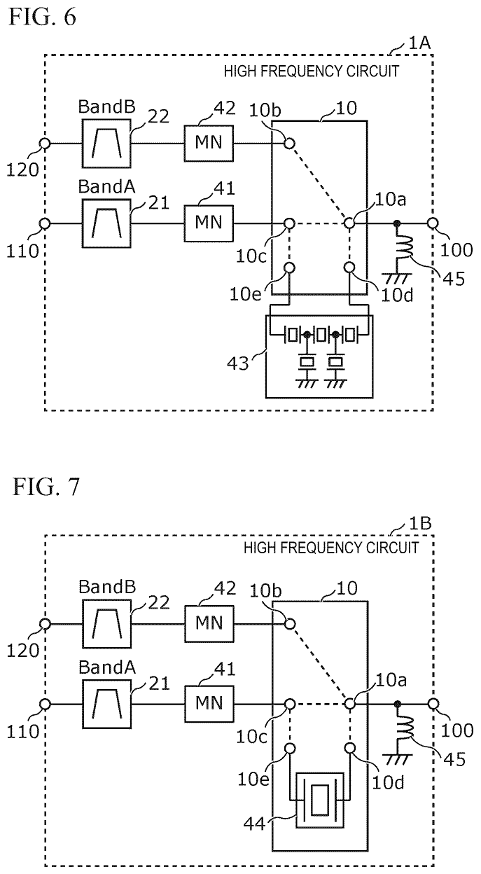

FIG. 6 is a circuit configuration diagram of a high frequency circuit 1A according to Variation 1. As shown in FIG. 6, the high frequency circuit 1A includes a switch 10, filters 21 and 22, an acoustic wave resonance circuit 43, matching circuits 41 and 42, an inductor 45, an antenna connection terminal 100, and high frequency output terminals 110 and 120. The high frequency circuit 1A according to Variation 1 differs from the high frequency circuit 1 according to the embodiment in that it has the acoustic wave resonance circuit 43 instead of the acoustic wave resonator 40. The following description of the high frequency circuit 1A according to Variation 1 will focus on the different points, omitting the description of the points that are the same as those of the high frequency circuit 1 according to the embodiment.

The acoustic wave resonance circuit 43 has a plurality of acoustic wave resonators, and has its first end connected to the terminal 10d and its second end connected to the terminal 10e. Specifically, the acoustic wave resonance circuit 43 has three series arm resonators arranged in series in a path connecting the first end and the second end, and two parallel arm resonators connected between the path and the ground. In the above-described configuration, by differentiating the resonant frequency and anti-resonant frequency of each resonator, the acoustic wave resonance circuit 43 can function as a band elimination filter. Thus, the acoustic wave resonance circuit 43 can have a wide attenuation band formed by a plurality of attenuation poles with different frequencies, while the single acoustic wave resonator 40 has a narrow attenuation band formed by a single attenuation pole.

Note that the acoustic wave resonance circuit 43 is not limited to being composed of five acoustic wave resonators, but may include two or more acoustic wave resonators. The acoustic wave resonance circuit 43 is not limited to the ladder-type configuration illustrated in the present variation, but may include longitudinally coupled resonators, or may have any other circuit configuration.

### [1.6 Circuit Configuration of High Frequency Circuit 1B According to Variation 2]

FIG. 7 is a circuit configuration diagram of a high frequency circuit 1B according to Variation 2. As shown in FIG. 7, the high frequency circuit 1B includes a switch 10, filters 21 and 22, an acoustic wave resonator 44, matching circuits 41 and 42, an inductor 45, an antenna connection terminal 100, and high frequency output terminals 110 and 120. The high frequency circuit 1B according to Variation 2 differs from the high frequency circuit 1 according to the embodiment in that the acoustic wave resonator 44 is formed inside the switch 10. The following description of the high frequency circuit 1B according to Variation 2 will focus on the different points, omitting the description of the same points as those of the high frequency circuit 1 according to the embodiment.

The switch 10 is an example of a switch circuit and has a terminal 10a (first terminal), a terminal 10b (third terminal), a terminal 10c (second terminal), a terminal 10d (fourth terminal), and a terminal 10e (fifth terminal). The switch 10 switches the connection and disconnection between the terminal 10a and the terminal 10c, switches the connection and disconnection between the terminal 10a and the terminal 10b, switches the connection and disconnection between the terminal 10a and the terminal 10d, and switches the connection and disconnection between the terminal 10c and the terminal 10e.

The switch 10 is composed of a semiconductor IC, and is a multi-connection type switch circuit composed of, for example, an SPST type first switch element having the terminal 10a and the terminal 10b, an SPST type second switch element having the terminal 10a and the terminal 10c, an SPST type third switch element having the terminal 10a and the terminal 10d, and an SPST type fourth switch element having the terminal 10c and the terminal 10e. The above semiconductor IC is configured using, for example, a CMOS (Complementary Metal Oxide Semiconductor), and includes a silicon substrate. Specifically, the above semiconductor IC may be manufactured by a SOI (Silicon on Insulator) process. The semiconductor IC may be composed of at least one of GaAs, SiGe, and GaN, and is not limited to these materials.

The acoustic wave resonator 44 has its first end connected to the terminal 10d and its second end connected to the terminal 10e, and is included in the semiconductor IC constituting the switch 10. When the acoustic wave resonator 44 is a surface acoustic wave resonator, a silicon substrate of a semiconductor IC, for example, is applied as the high acoustic velocity support substrate 51 shown in FIG. 2A. When the acoustic wave resonator 44 is a bulk acoustic wave resonator, a silicon substrate of a semiconductor IC, for example, is applied as the support substrate 65 shown in FIG. 2C.

Thus, since the acoustic wave resonator 44 is formed inside the switch 10, the high frequency circuit 1B can be miniaturized.

### [1.7 Circuit Configuration of High Frequency Circuit 1C According to Variation 3]

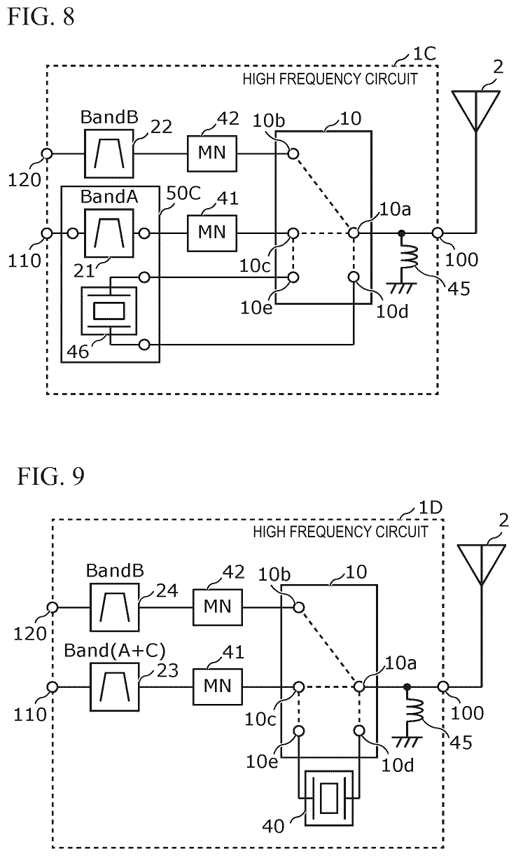

FIG. 8 is a circuit configuration diagram of a high frequency circuit 1C according to Variation 3. As shown in FIG. 8, the high frequency circuit 1C includes a switch 10, filters 21 and 22, an acoustic wave resonator 46, matching circuits 41 and 42, an inductor 45, an antenna connection terminal 100, and high frequency output terminals 110 and 120. The high frequency circuit 1C according to Variation 3 differs from the high frequency circuit 1 according to the embodiment in that the acoustic wave resonator 46 is formed on the same substrate as the filter 21. The following description of the high frequency circuit 1C according to Variation 3 will focus on the different points, omitting the description of the points that are the same as those of the high frequency circuit 1 according to the embodiment.

The acoustic wave resonator 46 has its first end connected to the terminal 10d and its second end is connected the terminal 10e. The acoustic wave resonator 46 and the filter 21 are formed on the same (common) substrate 50C. If both the acoustic wave resonator 46 and the filter 21 utilize surface acoustic waves, the substrate 50C may be a piezoelectric substrate or a silicon substrate. If both the acoustic wave resonator 46 and the filter 21 utilize bulk acoustic waves, the substrate 50C may be a silicon substrate.

The filter that shares the substrate with the acoustic wave resonator 46 may alternatively be the filter 22, instead of the filter 21.

Thus, since the acoustic wave resonator 46 and the filter 21 or 22 are formed on the common substrate 50C, the high frequency circuit 1C can be miniaturized.

### [1.8 Circuit Configuration and Signal Transmission State of High Frequency Circuit 1D According to Variation 4]

FIG. 9 is a circuit configuration diagram of a high frequency circuit 1D according to Variation 4. As shown in FIG. 9, the high frequency circuit 1D includes a switch 10, filters 23 and 24, an acoustic wave resonator 40, matching circuits 41 and 42, an inductor 45, an antenna connection terminal 100, and high frequency output terminals 110 and 120. The high frequency circuit 1D according to Variation 4 has different bandpass characteristics of the filters 23 and 24 compared to the high frequency circuit 1 according to the embodiment. The following description of the high frequency circuit 1D according to Variation 4 will focus on the different points, omitting the description of the same points as those of the high frequency circuit 1 according to the embodiment.

The filter 23 is an example of a first filter, with its input end connected to the terminal 10c and its output end connected to the high frequency output terminal 110, and has a first pass band that includes at least a part of band A (first band) and at least a part of band C (third band).

The filter 24 is an example of a second filter, with its input end connected to the terminal 10b and its output end connected to the high frequency output terminal 120, and has a second pass band that includes at least a part of band B (second band).

According to the above-described configuration of the high frequency circuit 1D, it is possible to realize transmission of band A alone, transmission of band C alone, transmission of band B alone, and transmission of band A and band B simultaneously. It is possible to select whether or not to connect the acoustic wave resonator 40 in series with the filter 23 when transmitting the signal of band A alone, when transmitting the signal of band C alone, and when transmitting the signals of band A and band B simultaneously. The acoustic wave resonator 40 has a capacitive impedance and further, can form an attenuation pole in the vicinity of the anti-resonant frequency. Thus, not only the return loss of the signal of band B is reduced by the capacitive impedance of the acoustic wave resonator 40, but also the attenuation characteristics of the filter 23 can be improved. Thus, it is possible to provide the high frequency circuit 1D that can transmit the signals in a plurality of bands with low loss and transmit the signals in adjacent bands with high attenuation.

Next, the signal transmission state of band A, band B and band C in the high frequency circuit 1D is described.

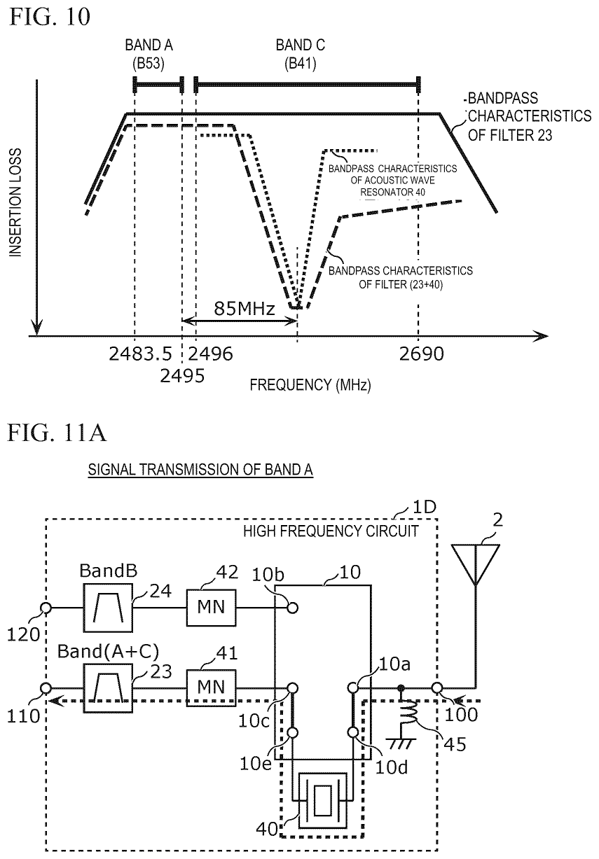

FIG. 10 is a graph showing filter bandpass characteristics of the high frequency circuit 1D according to Variation 4. FIG. 10 illustrates the bandpass characteristics of the filter 23, the acoustic wave resonator 40, and a series-connected circuit of the filter 23 and the acoustic wave resonator 40. In the present variation, band A is, for example, Band 53 (2483.5-2495 MHz) for 4G-LTE, and Band C is, for example, Band 41 (2496-2690 MHz) for 4G-LTE.

As shown in FIG. 10, the pass band of the filter 23 includes both band A and band C. The signal in band C is passed through the filter 23. On the other hand, during the signal transmission of band A, there is a requirement to attenuate the band on the higher frequency side by a predetermined frequency (for example, 85 MHZ) from the high frequency end of band A. The attenuation band is included in band C. Band B, although no specific example is given, is a band that does not overlap with band A and band C.

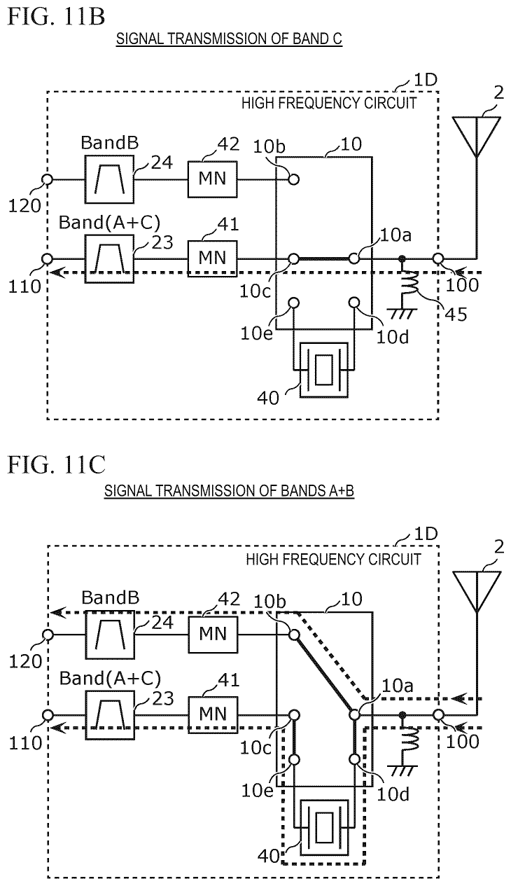

FIG. 11A is a circuit state diagram of the high frequency circuit 1D according to Variation 4, when the signal of band A is transmitted alone. FIG. 11B is a circuit state diagram of the high frequency circuit 1D according to Variation 4, when the signal of band C is transmitted alone. FIG. 11C is a circuit state diagram of the high frequency circuit 1D according to Variation 4, when the signals of band A and band B are transmitted simultaneously.

First, when the signal of band A is transmitted alone, it is assumed that the requirement for the above-described attenuation band on the higher frequency side than band A cannot be satisfied. In such a case, as shown in FIG. 11A, the acoustic wave resonator 40 is connected in series with the filter 23 to ensure high attenuation in the above-described attenuation band in the signal transmission of band A. In the present example, the anti-resonant frequency of the acoustic wave resonator 40 can be included in band C. Thus, the series-connected circuit of the filter 23 and the acoustic wave resonator 40 can have bandpass characteristics with high attenuation in the above-described attenuation band.

Specifically, as shown in FIG. 11A, in the switch 10, the terminal 10a and the terminal 10b are disconnected, the terminal 10a and the terminal 10d are connected, the terminal 10c and the terminal 10e are connected, and the terminal 10a and the terminal 10c are disconnected. Thus, the signal of band A passes through the antenna 2, the antenna connection terminal 100, the terminal 10a, the terminal 10d, the acoustic wave resonator 40, the terminal 10e, the terminal 10c, the matching circuit 41, and the filter 23 to be output from the high frequency output terminal 110.

Thus, when the signal of band A is transmitted alone, it is possible to have high attenuation in a predetermined band.

When the signal of band C is transmitted alone, it is assumed that there is no need to ensure attenuation of the adjacent band A. In such a case, as shown in FIG. 11B, the acoustic wave resonator 40 is not connected to the filter 23 to ensure low loss in the signal transmission of band C.

Specifically, as shown in FIG. 11B, in the switch 10, the terminal 10a and the terminal 10b are disconnected, the terminal 10a and the terminal 10d are disconnected, the terminal 10c and the terminal 10e are disconnected, and the terminal 10a and the terminal 10c are connected. Thus, the signal of band C passes through the antenna 2, the antenna connection terminal 100, the terminal 10a, the terminal 10c, the matching circuit 41, and the filter 23 to be output from the high frequency output terminal 110.

Thus, when the signal of band C is transmitted alone, since the acoustic wave resonator 40 is not connected, the signal of band C can be transmitted with low loss.

When the signal of band A and the signal of band B are transmitted simultaneously, since the signal of band B interferes with the signal of band A, it is assumed that low-loss transmission of band A and band B cannot be satisfied. In such a case, as shown in FIG. 11C, the acoustic wave resonator 40 is connected in series with the filter 23 to reduce the return loss in the frequency band of band B in the signal path of band A from the terminal 10a to the high frequency output terminal 110.

Specifically, as shown in FIG. 11C, in the switch 10, the terminal 10a and the terminal 10b are connected, the terminal 10a and the terminal 10d are connected, the terminal 10c and the terminal 10e are connected, and the terminal 10a and the terminal 10c are disconnected. Thus, the signal of band A passes through the antenna 2, the antenna connection terminal 100, the terminal 10a, the terminal 10d, the acoustic wave resonator 40, the terminal 10e, the terminal 10c, the matching circuit 41, and the filter 23 to be output from the high frequency output terminal 110. On the other hand, the signal of band B passes through the antenna 2, the antenna connection terminal 100, the terminal 10a, the terminal 10b, the matching circuit 42, and the filter 24 to be output from the high frequency output terminal 120.

Thus, since leakage of the signal of band B into the signal path of band A from the terminal 10a to the high frequency output terminal 110 can be suppressed, it is possible to transmit the signal of band B with low loss in the signal path of band B from the terminal 10a to the high frequency output terminal 120.

Since the signals of band A and band C can be transmitted using the common filter 23 instead of separately providing matching circuits for the signal of band A and the signal of band C, respectively, the number of components in the high frequency circuit 1D can be reduced, thereby promoting miniaturization.

### [2. Effects and the Like]

As described above, the high frequency circuit 1 according to the present embodiment includes: a switch 10 that has terminals 10a, 10b, 10c, and 10d, and that switches the connection and disconnection between the terminal 10a and the terminal 10b, switches the connection and disconnection between the terminal 10a and the terminal 10c, and switches the connection and disconnection between the terminal 10a and the terminal 10d; a filter 21 that has a first pass band including at least a part of band A and that is connected to the terminal 10c; a filter 22 that has a second pass band including at least a part of band B and that is connected to the terminal 10b; and an acoustic wave resonator 40 that has its first end connected to the terminal 10d and its second end connected to the terminal 10c.

Thus, the high frequency circuit 1 can realize transmission of band A alone, transmission of band B alone, and transmission of band A and band B simultaneously. When the signal of band A is transmitted alone, and when the signals of band A and band B are transmitted simultaneously, it is possible to select whether or not to connect the acoustic wave resonator 40 in series with the filter 21. The acoustic wave resonator 40 has a capacitive impedance and further, can form an attenuation pole in the vicinity of the anti-resonant frequency. Thus, not only the return loss of the signal of band B is reduced by the capacitive impedance of the acoustic wave resonator 40, but also the attenuation characteristics of the filter 21 can be improved. Thus, it is possible to provide the high frequency circuit 1 that can transmit the signals in a plurality of bands with low loss and transmit the signals in adjacent bands with high attenuation.

Further, for example, in the high frequency circuit 1, the switch 10 may simultaneously perform two or more of the following connections: the connection between the terminal 10a and the terminal 10b, the connection between the terminal 10a and the terminal 10c, and the connection between the terminal 10a and the terminal 10d.

Thus, the switch 10 can function as a multi-connection type switch circuit.

Further, for example, in the high frequency circuit 1, the switch 10 may further have a terminal 10e to switch the connection and disconnection between the terminal 10c and the terminal 10e, and the second end of the acoustic wave resonator 40 may be connected to the terminal 10c via the terminal 10e.

Thus, it is possible to switch the connection and disconnection between the terminal 10e and the terminal 10c, and to realize a highly accurate disconnected state between the filter 21 and the acoustic wave resonator 40.

Further, for example, in the high frequency circuit 1, when the terminal 10a and the terminal 10d are in a connected state, the terminal 10c and the terminal 10e may be in a connected state; and when the terminal 10a and the terminal 10d are in a disconnected state, the terminal 10c and the terminal 10e may be in a disconnected state.

Thus, connection and disconnection between the filter 21 and the acoustic wave resonator 40 can be realized with high accuracy.

Further, for example, in the high frequency circuit 1, when the signal of band A and the signal of band B are transmitted simultaneously, the terminal 10a and the terminal 10c may be in a disconnected state, the terminal 10a and the terminal 10b may be in a connected state, and the terminal 10a and the terminal 10d may be in a connected state; and when the signal of only band A, among band A and band B, is transmitted, the terminal 10a and the terminal 10c may be in a connected state, the terminal 10a and the terminal 10b may be in a disconnected state, and the terminal 10a and the terminal 10d may be in a disconnected state.

Thus, when the signals of bands A and B are transmitted simultaneously, it is possible to not only reduce the return loss of the signal of band B passing through the signal path of band A from the terminal 10a to the high frequency output terminal 110, but also improve the attenuation in the frequency band of band B in the signal path of band A. Thus, the signals of band A and band B can be transmitted with low loss. When the signal of band A is transmitted alone, the signal of band A can be transmitted without necessarily interference from the signal of band B; and further, since the acoustic wave resonator 40 is not connected, the signal of band A can be transmitted with low loss.

Further, for example, in the high frequency circuit 1, the anti-resonant frequency of the acoustic wave resonator 40 may be included in the second pass band.

Thus, the series-connected circuit of the filter 21 and the acoustic wave resonator 40 can have bandpass characteristics with high attenuation in band B.

Further, for example, in the high frequency circuit 1, when the signal of band A and the signal of band B are transmitted simultaneously, the terminal 10a and the terminal 10c may be in a connected state, the terminal 10a and the terminal 10b may be in a connected state, and the terminal 10a and the terminal 10d may be in a disconnected state; and when the signal of only band A, among band A and band B, is transmitted, the terminal 10a and the terminal 10c may be in a disconnected state, the terminal 10a and the terminal 10b may be in a disconnected state, and the terminal 10a and the terminal 10d may be in a connected state.

Thus, when the signals of bands A and B are transmitted simultaneously, since the acoustic wave resonator 40 is not connected, the signals of band A and band B can be transmitted with low loss. Further, when the signal of band A is transmitted alone, attenuation in a predetermined frequency band can be enhanced.

Further, for example, in the high frequency circuit 1D according to Variation 4, when the first pass band includes at least a part of band A and at least a part of band C, and only the signal of band A, among band A and band C, is transmitted, the terminal 10a and the terminal 10c may be in a disconnected state, and the terminal 10a and the terminal 10d may be in a connected state.

Thus, when the signal of band A is transmitted alone, it is possible to have high attenuation in a predetermined band. Since the signals of band A and band C can be transmitted using the common filter 23 instead of separately providing matching circuits for the signal of band A and the signal of band C, respectively, the number of components in the high frequency circuit 1D can be reduced, thereby promoting miniaturization.

Further, for example, in the high frequency circuit 1D, the anti-resonant frequency of the acoustic wave resonator 40 may be included in band C.

Thus, the series-connected circuit of the filter 23 and the acoustic wave resonator 40 can have bandpass characteristics with high attenuation in band C.

Further, for example, in the high frequency circuit 1D, when only the signal of band C, among band A and band C, is transmitted, the terminal 10a and the terminal 10c may be in a connected state and the terminal 10a and the terminal 10d may be in a disconnected state.

Thus, when the signal of band C is transmitted alone, since the acoustic wave resonator 40 is not connected, the signal of band C can be transmitted with low loss.

Further, for example, in the high frequency circuit 1B according to Variation 2, the switch 10 may be composed of a semiconductor IC, and the acoustic wave resonator 44 may be included in the semiconductor IC.

Thus, since the acoustic wave resonator 44 is formed inside the switch 10, the high frequency circuit 1B can be miniaturized.

Further, for example, in the high frequency circuit 1C according to Variation 3, at least one of the filters 21 and 22 and the acoustic wave resonator 46 may be formed on the same substrate 50C.

Thus, since the acoustic wave resonator 46 and the filter 21 or 22 are formed on the common substrate 50C, the high frequency circuit 1C can be miniaturized.

Further, for example, in the high frequency circuit 1A according to Variation 1, the acoustic wave resonance circuit 43 composed of a plurality of acoustic wave resonators may be connected between the terminal 10c and the terminal 10d.

Thus, the acoustic wave resonance circuit 43 can have a wide attenuation band formed by a plurality of attenuation poles with different frequencies, while the single acoustic wave resonator 40 has a narrow attenuation band formed by a single attenuation pole.

Further, the communication apparatus 5 according to the present embodiment includes an RFIC 4 that processes the high frequency signal and the high frequency circuit 1 that transmits the high frequency signal between the RFIC 4 and the antenna 2.

Thus, the effect of the high frequency circuit 1 can be realized by the communication apparatus 5.

### Other Embodiments and the Like

The high frequency circuit and the communication apparatus according to the embodiments of the present disclosure have been described above with reference to the embodiment and variations; however, the high frequency circuit and the communication apparatus according to the present disclosure are not limited to the embodiment and variations described above. The present disclosure also includes other embodiments obtained by combining any of the components in the embodiment and variations described above, variations obtained by applying various variations conceived by those skilled in the art to the embodiment and variations described above without necessarily departing from the spirit of the present disclosure, and various devices incorporating the high frequency circuit and the communication apparatus described above.

For example, the high frequency circuit according to the embodiment described above is a receiving circuit that transmits the signal received by the antenna 2 to the RFIC 4, but it can also be applied as a transmitting circuit that transmits the transmission signal generated by the RFIC 4 to the antenna 2. When the high frequency circuit according to the embodiment described above is applied to a transmitting circuit, a power amplifier is arranged between the high frequency circuit and the RFIC 4 instead of the low-noise amplifier.

Further, for example, other circuit elements, wiring and/or the like may be inserted between the paths connecting each circuit element and signal path disclosed in the drawings in the high frequency circuit and communication apparatus according to the embodiment and variations described above.

### INDUSTRIAL APPLICABILITY

The present disclosure, as a high frequency circuit arranged in a multi-band adaptive front-end section, can be widely used in communication devices such as cellular phones.

### REFERENCE SIGNS LIST

1, 1A, 1B, 1C, 1D high frequency circuit
2 antenna
4 RFIC
5 communication apparatus
10 switch
10a, 10b, 10c, 10d, 10e terminal
21, 22, 23, 24 filter
31, 32 low-noise amplifier
40, 44, 46 acoustic wave resonator
41, 42 matching circuit
43 acoustic wave resonance circuit
45 inductor
50, 50C substrate
51 high acoustic velocity support substrate
52 low acoustic velocity film
53 piezoelectric film
54 IDT electrode
55, 58 protective layer
57 piezoelectric single crystal substrate
60a, 60b comb-shaped electrode
61a, 61b electrode finger
62a, 62b busbar electrode
65 support substrate
66 lower electrode
67 piezoelectric layer
68 upper electrode
100 antenna connection terminal
110, 120 high frequency output terminal
540 adhesion layer
542 main electrode layer

1. A high frequency circuit comprising:
a switch circuit that has a first terminal, a second terminal, a third terminal, and a fourth terminal, and that is configured to selectively switch connection of the first terminal to the second terminal, to the third terminal, and to the fourth terminal;
a first filter that has a first pass band and that is connected to the second terminal, the first pass band comprising at least part of a first band;
a second filter that has a second pass band and that is connected to the third terminal, the second pass band comprising at least a part of a second band; and
an acoustic wave resonator that has a first end connected to the fourth terminal and a second end connected to the second terminal.

2. The high frequency circuit according to claim 1, wherein the switch circuit is configured to simultaneously connect the first terminal to at least two of the second terminal, the third terminal, and the fourth terminal.

3. The high frequency circuit according to claim 1,
wherein the switch circuit further has a fifth terminal, and is configured to selectively connect the second terminal to the fifth terminal, and
the second end of the acoustic wave resonator is connected to the second terminal via the fifth terminal.

4. The high frequency circuit according to claim 3,
wherein, when the first terminal is connected to the fourth terminal, the second terminal is connected to the fifth terminal, and
wherein when the first terminal is not connected to the fourth terminal, the second terminal is not connected to the fifth terminal.

5. The high frequency circuit according to claim 1,
wherein when a signal of the first band and a signal of the second band are transmitted simultaneously, the first terminal is not connected to the second terminal, the first terminal is connected to the third terminal, and the first terminal is connected to the fourth terminal, and
wherein when only the signal of the first band, among the first band and second band, is transmitted, the first terminal is connected to the second terminal, the first terminal is not connected to the third terminal, and the first terminal is not connected to the fourth terminal.

6. The high frequency circuit according to claim 1, wherein an anti-resonant frequency of the acoustic wave resonator is in the second pass band.

7. The high frequency circuit according to claim 1,
wherein when a signal of the first band and a signal of the second band are transmitted simultaneously, the first terminal is connected to the second terminal, the first terminal is connected to the third terminal, and the first terminal is not connected to the fourth terminal, and
wherein when only the signal of the first band, among the first band and the second band, is transmitted, the first terminal is not connected to the second terminal, the first terminal is not connected to the third terminal, and the first terminal is connected to the fourth terminal.

8. The high frequency circuit according to claim 1,
wherein the first pass band comprises at least a part of the first band and at least a part of a third band, and
wherein when only a signal of the first band, among the first band and the third band, is transmitted, the first terminal is not connected to the second terminal and the first terminal is connected to fourth terminal.

9. The high frequency circuit according to claim 8, wherein an anti-resonant frequency of the acoustic wave resonator is in the third band.

10. The high frequency circuit according to claim 8, wherein when only a signal of the third band, among the first band and third band, is transmitted, the first terminal is connected to the second terminal, and the first terminal is not connected to the fourth terminal.

11. The high frequency circuit according to claim 1,
wherein the switch circuit is in a semiconductor integrated circuit (IC), and
wherein the acoustic wave resonator is in the semiconductor IC.

12. The high frequency circuit according to claim 1, wherein the first filter or the second filter are on a same substrate as the acoustic wave resonator.

13. The high frequency circuit according to claim 1, wherein a plurality of acoustic wave resonators is connected between the second terminal and the fourth terminal.

14. A communication apparatus comprising:
a signal processing circuit configured to process a high frequency signal; and
the high frequency circuit according to claim 1 configured to transmit the high frequency signal between the signal processing circuit and an antenna.
